(19) United States
(12) Patent Application Publication
(10) Pub. No.: US 2022/0109078 A1
(43) Pub. Date: Apr. 7, 2022

(54) SEMI-TRANSPARENT MULTI-CELL PHOTOVOLTAIC DEVICE

(71) Applicant: Garmin Switzerland GmbH, Schaffhausen (CH)

(72) Inventors: Mohamed Bouchoucha, Les Pennes Mirabeau (FR); Brice Arrazat, Bouc Bel Air (FR)

(21) Appl. No.: 17/644,514

(22) Filed: Dec. 15, 2021

Related U.S. Application Data
(63) Continuation of application No. PCT/IB2019/055253, filed on Jun. 21, 2019.

(51) Int. Cl. H01L 31/0463; H01L 31/0468

(52) U.S. Cl. CPC H01L 31/0463; H01L 31/0468

(57) ABSTRACT

A semi-transparent photovoltaic module comprises a basic 2D pattern representing an arrangement of an electrically conductive zone and electrically non-conductive zones such that any point in the electrically conductive zone is electrically connected to any other point of the zone and the electrically conductive zone is a regular or pseudo-regular structure formed by an elementary geometrical figure. The module additionally comprises one or more active isolation lines and a plurality of non-functional isolation lines that are mutually parallel.

### RELATED APPLICATIONS

The present application is a continuation of, and claims priority benefit to, co-pending international application entitled, “SEMI-TRANSPARENT MULTI-CELL PHOTOVOLTAIC DEVICE,” International Application No. PCT/IB2019/055253, filed Jun. 21, 2019, which is hereby incorporated by reference into the current application in its entirety.

### BACKGROUND

Embodiments of the present invention relate to the field of thin-film semi-transparent photovoltaic devices, having a multi-cell architecture. These devices are intended to produce electrical energy and/or to function as photovoltaic sensors or transducers.

A thin-film photovoltaic cell is made up of at least one substrate, a first transparent electrode, a second generally metal electrode, and an absorber layer. Thin-film means photovoltaic layers of any type (organic, inorganic), and of which the thickness of the absorber does not exceed approximately ten micrometers.

A thin-film photovoltaic module is made up of a plurality of thin-film photovoltaic cells. It is generally made up of a plurality of photovoltaic cells which are electrically connected in series, in order to increase the electrical voltage at the terminals of the module. Methods are known for serializing photovoltaic cells by means of successive steps of isolation and interconnection of different thin films which make up said cells. These steps are described for example in the document EP0500451-131.

In visible light, a semi-transparent thin-film photovoltaic cell comprises a plurality of active opaque photovoltaic zones which are separated by transparent zones. The photovoltaic zones may be of any shape and size, such that they cannot be distinguished by the naked eye. In order to achieve this, the width of the photovoltaic zones is preferably less than 200 micrometers. In an embodiment known to a person skilled in the art, the active photovoltaic zones or the transparent zones are organized in networks of linear, circular or polygonal elementary geometrical structures. The transparency of the photovoltaic cell depends on the surface fraction occupied by the active opaque photovoltaic zones. The patent WO2014/188092-A1 describes the architecture of a single semi-transparent thin-film photovoltaic cell, referred to as a mono cell. In an embodiment which is recommended in this document, the transparent zones are arranged in the transparent electrode as well as the metal electrode and the absorber, in order to increase the transmission of the light in the region of the transparent zones, since by reducing the number of interfaces the optical phenomena of reflections at the interfaces are minimized.

Placing semi-transparent mono cells in series, by means of the method described in the document EP0500451-B1 cited above, would have the disadvantage of creating isolation lines which would not be integrated in the initial design and which would in fact become visible to the human eye, in particular in the case of polygonal patterns.

### BRIEF DESCRIPTION OF THE DRAWING FIGURES

FIG. 1A is a diagram showing a grid cell of a network of squares.

FIG. 1B is a diagram showing the network of squares associated with the grid cell of FIG. 1A and forming a first basic 2D pattern.

FIG. 1C is a diagram showing the first basic 2D pattern of FIG. 1B to which two collection buses have been added.

FIG. 1D is a diagram showing the first basic 2D pattern of FIG. 1C together with the collection buses thereof, to which an active isolation line has been added.

FIG. 1E is a diagram showing the first basic 2D pattern containing an active isolation line and two non-functional isolation lines.

FIG. 1F is a diagram showing the first basic 2D pattern containing an active isolation line and ten non-functional isolation lines.

FIG. 2A is a diagram showing a grid cell of a regular hexagonal network.

FIG. 2B is a diagram showing a regular hexagonal network which is associated with the grid cell of FIG. 2A and forming a second basic 2D pattern.

FIG. 2C is a diagram showing the second basic 2D pattern of FIG. 2B containing an active isolation line and eight non-functional isolation lines.

FIG. 3A is a diagram showing a third basic 2D pattern, the elementary geometrical figure of which is any shape arranged within a diamond-type network, associated with the collection buses thereof.

FIG. 3B is a diagram showing the third 2D pattern of FIG. 3A containing two active isolation lines and ten non-functional isolation lines.

### DETAILED DESCRIPTION

Embodiments of the present invention provide a photovoltaic device which improves the visual quality of a photovoltaic module made up of a plurality of semi-transparent thin-film cells.

In various configurations, the improvement in the visual quality is achieved by placing the isolation lines such that they are less visible, or indeed invisible, for an observer located a few centimeters from the surface of said module.

In the remainder of the document, a grid cell of a network is defined by the vectors U and V thereof, as well as its elementary geometrical figure which, repeated periodically in the two spatial dimensions according to the directions of the vectors U and V, results in a periodic network which is also referred to as a regular structure. When a grid cell is repeated according to the directions of the vectors U and V, but not in a periodic manner in the two spatial dimensions, this repetition results in a pseudo-regular structure. In both cases, the elementary geometrical figure can be made up of one or more patterns.

Furthermore, proceeding from a semi-transparent photovoltaic mono cell, it is possible to create a semi-transparent photovoltaic module made up of a plurality of cells. In order to achieve this, it is necessary to remove material within the electrically conductive zone and the collection buses, such that a path which electrically isolates two parts of the photovoltaic cell is created. This path is referred to as an active isolation line. If a path is created only within the electrically conductive zone and does not intercept the collection buses, then it is referred to as a non-functional isolation line.

The semi-transparent module may be formed by:
a basic 2D pattern representing an arrangement of an electrically conductive zone and electrically non-conductive zones, and defined by the fact that:
   any point in the electrically conductive zone is electrically connected to any other point of said zone;
   the electrically conductive zone is a regular or pseudo-regular structure formed by an elementary geometrical figure, which is repeated according to a regular or pseudo-regular grid, the grid cell of which is defined by the vectors U and V thereof;
   the electrically conductive zone is mainly made up of active photovoltaic zones, but can be made up locally of materials that are only conductive;
   the electrically non-conductive zones are transparent zones;
collection buses;

said pattern being characterized in that it further contains one or more active isolation lines and a plurality of non-functional isolation lines, said isolation lines being mutually parallel and being directed according to the direction of one of the vectors U, V, U+V or U−V, and/or according to one of the edges of the elementary geometrical figure.

Advantageously, the isolation lines (whether these be active or non-functional) are equidistant with respect to one another, so as to form a sub-network which is perfectly integrated within the 2D pattern. One of the means for making it possible to achieve this integration is to form the isolation lines so as to be equidistant by a distance corresponding to the value m*∥U∥ or k*∥V∥, where ∥ ∥ represents the norm of the associated vector, where m and k are natural non-zero integers.

Advantageously, said isolation lines are of the same width L. Preferably, said width L does not exceed 50% of the width of the electrically conductive zones.

The width L is advantageously less than 100 micrometers.

Advantageously, when an isolation line passes through an electrically conductive zone of the basic 2D pattern, it splits it locally into two electrically conductive zones of equal widths.

Advantageously, the 2D patterns are made up of at least a circle, a square, a hexagon, an octagon, a diamond.

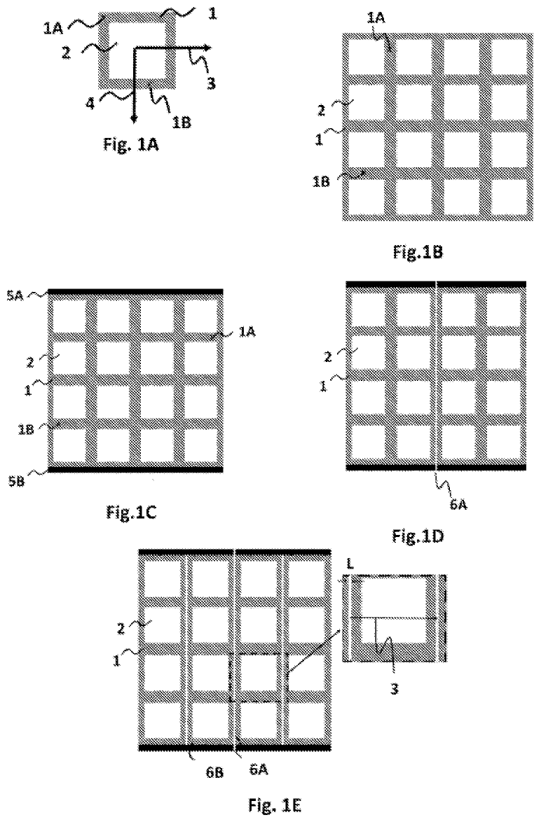

FIG. 1A shows a grid cell of a network of squares. It is defined by the square elementary geometrical shape thereof and by the two spatial directions represented by the vectors U (3) and V (4). The electrically conductive zone (1) is arranged such that any point (1A) in the said zone (1) is electrically connected to any other point (1B) of this zone (1).

FIG. 1B shows a network of squares based on the grid cell of FIG. 1A. The geometrical figure of FIG. 1A has been repeated periodically according to the vector U (3) and according to the vector V (4) in order to form a first basic 2D pattern which has the following properties:
any point (1A) in the electrically conductive zone (1) is electrically connected to any other point (1B) of said zone (1);
the electrically conductive zone (1) is a regular structure of squares which forms a grid;
the electrically conductive zone (1) is mainly made up of active photovoltaic zones, but can be made up locally of materials that are only conductive;
the electrically non-conductive zones (2) are transparent zones.

FIG. 1C shows the first basic 2D pattern of FIG. 1B, to which two collection buses 5A and 5B have been added. This particular configuration corresponds to a single photovoltaic cell.

Furthermore, proceeding from this semi-transparent photovoltaic mono cell, it is possible to create a semi-transparent photovoltaic module made up of a plurality of cells. In order to achieve this, it is necessary to remove material within the electrically conductive zone (1) and the collection buses (5A and 5B), such that a path which electrically isolates two parts of the photovoltaic cell is created. This path is referred to as an active isolation line. If a path is created only within the electrically conductive zone (1) of the basic 2D pattern and does not intercept the collection buses (5A and 5B), then it is referred to as a non-functional isolation line.

The invention may include arranging a plurality of isolation lines (active or non-functional) within the basic 2D pattern and/or the collection buses, in order to create a multi-cell photovoltaic module within which said isolation lines are less visible, indeed invisible, for an observer located a few centimeters from the surface of said module.

In the remainder of the document, a photovoltaic direction is defined by at least one of the following characteristics:
the photovoltaic direction corresponds to the direction of one of the vectors U, V, U+V or U−V;
the photovoltaic direction is in parallel with one of the sides of the elementary geometrical figure.

FIG. 1D shows the first basic 2D pattern together with the collection buses thereof, to which an active isolation line (6A) has been added. Said isolation line (6A) makes it possible to transform the photovoltaic cell described in FIG. 1C into two electrically separate cells (C1 and C2) according to a photovoltaic direction. In this example, said direction is both according to the direction of the vector U (3) and according to the direction of one of the sides of the square geometrical figure. The reconnection of the cells (C1 and C2) in series or in parallel takes place in the region of the buses (5A and 5B) by methods known to a person skilled in the art.

However, said isolation line (6A) creates a visual disturbance within the first basic 2D pattern. Whatever the size and the location of the active isolation lines (6A) within the 2D pattern, said lines create symmetry breaks of the network, locally, which are visible to the naked eye since they cannot, in order to ensure their electrical isolation function, be of a size of less than 0.1 μm, which would be imperceptible to the naked eye at a distance of 30 cm from the module.

FIG. 1E shows a first embodiment of the photovoltaic module according to the invention, in which the first basic 2D pattern contains an active isolation line (6A) and two non-functional isolation lines (6B) which are in parallel with one another and according to a photovoltaic direction. The non-functional isolation lines (6B) make it possible to homogenize the visual impact of the active isolation lines (6A), making it possible to integrate a network of transparent lines (6A and 6B) within the first basic 2D pattern. The non-functional isolation lines (6B) are distinct from the active isolation lines (6B) because they do not electrically split the collection buses into two electrically independent buses.

In order to further minimize the visual impact of the isolation lines (active and non-functional) within the basic 2D pattern, it is recommended that the isolation lines:
be equidistant;
be of the same width L;
be of a width smaller than the width of the electrically conductive zones through which they pass.

In the example of FIG. 1E, the isolation lines are equidistant by a distance equal to the norm of the vector U: ∥U∥. Moreover, the split the active photovoltaic part, through which they pass, into two zones of the same width.

FIG. 1F shows a second embodiment of the photovoltaic module according to the invention, in which the first basic 2D pattern contains an active isolation line (6A) and ten non-functional isolation lines (6B) which are in parallel with one another and of the same direction as the vector U−V.

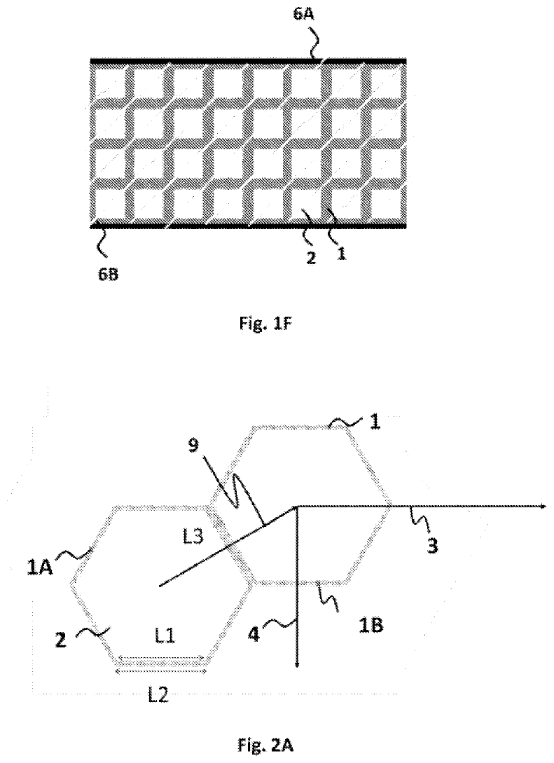

FIG. 2A shows a grid cell of a regular hexagonal network. It is defined by the square elementary geometrical figure thereof made up by two regular hexagons, and by the two spatial directions represented by the vectors U (3) and V (4). In order to form the elementary geometrical figure, a first regular hexagon is used, the internal edge of which is of a length L1, and the external edge of which is of a length L2. The width of an edge of a hexagon is equal to half of L3. The second regular hexagon results from the translation of the first hexagon according to the vector W (9).

FIG. 2B shows a regular hexagonal network which is based on the grid cell of FIG. 2A and forms a second basic 2D pattern, associated with the collection buses (5A and 5B) thereof. The second basic 2D pattern satisfies the same properties as the first basic 2D pattern described in FIG. 1B.

FIG. 2C shows a third embodiment of the photovoltaic module according to the invention, in which the second basic 2D pattern contains an active isolation line (6A) and eight non-functional isolation lines (6B). In this case, too, the non-functional isolation lines (6B) make it possible to homogenize the visual impact of the active isolation line (6A), by integrating a network of transparent lines (6A and 6B) within the basic 2D pattern. The active isolation line (6A) forms two separate photovoltaic cells C1 and C2. The visual rendering of the photovoltaic module achieved by adding isolation lines (6A and 6B) is very similar to that of the photovoltaic mono cell described in FIG. 2B. The aim is indeed to preserve the visual aspect of a network of hexagons.

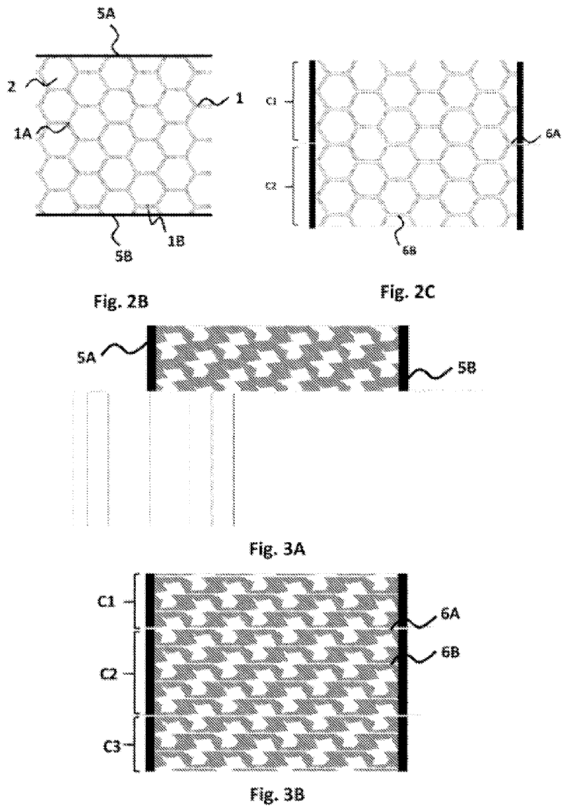

FIG. 3A shows a cell made up of a third basic 2D pattern, the elementary geometrical figure of which is any shape arranged within a diamond-type network, associated with the collection buses (5A and 5B) thereof.

FIG. 3B shows a fourth embodiment of the photovoltaic module according to the invention, in which the third 2D pattern contains two active isolation lines (6A) and ten non-functional isolation lines (6B). The two active isolation lines (6A) make it possible to form a photovoltaic module made up of three separate cells C1, C2 and C3.

Embodiments of the invention can be implemented under consideration of a photovoltaic module of which the thin films are deposited on a glass substrate. The absorber is based on amorphous silicon, and the electrodes are made up of a transparent conductive oxide at the front face and aluminum at the rear face. The stack of layers forming said photovoltaic module is protected by a transparent encapsulation resin. The semi-transparency is achieved either by local and selective laser ablation of the material, or by standard photolithography and wet (chemical etching solutions) or dry (plasma) etching methods.

In order to achieve a photovoltaic module having 78% transparency (i.e. 22% of the surface is opaque or photovoltaic), a solution consists in considering:
an elementary geometrical figure made up of two regular hexagons, and as described in the example of FIG. 2A:
   the first regular hexagon has an inside edge of 65.53 μm and an outside edge of 74.20 μm;
   the second regular hexagon results from the translation of the first hexagon according to the vector W of coordinates (11.30; 64.26);
the vectors U and V of the grid cell associated with said elementary geometrical figure are of the directions set out in FIG. 2A, the norm of U is 222.6 μm and the norm of V is 128.52 μm.

The width of the opaque lines between the adjacent hexagons is therefore 15 μm.

The isolation lines are positioned according to the direction of the vector U, and pass through the center of the hexagons.

1. A semi-transparent photovoltaic comprising:
a 2D pattern representing an arrangement of an electrically conductive zone and electrically non-conductive zones such that:
any point in the electrically conductive zone is electrically connected to any other point of the electrically conductive zone, wherein the electrically conductive zone is a regular structure formed by an elementary geometrical figure, which is repeated according to a regular grid, the grid cell of which is defined by the vectors U and V thereof; and
the electrically non-conductive zones are transparent zones;
a plurality of collection buses;
one or more active isolation lines defined as being a path which electrically isolates two parts of the photovoltaic cell by removal of material within the electrically conductive zone and collection buses, and
a plurality of non-functional isolation lines defined as being a path which electrically isolates two parts of the photovoltaic cell by removal of material only within the electrically conductive zone,
wherein the active isolation lines and non-functional isolation lines are mutually parallel and directed according to at least one of (1) the direction of one of the vectors U, V, U+V or U−V; and (2) one of the edges of the elementary geometrical figure.

2. The module of claim 1, wherein the active isolation lines and non-functional isolation lines are spaced equidistant from each other, in pairs.

3. The module of claim 2, wherein the active isolation lines and non-functional isolation lines are equidistant by a distance corresponding to the value m*∥U∥ or k*∥V∥, where ∥ ∥ represents the norm of the associated vector, where m and k are natural non-zero integers.

4. The module of claim 2, wherein the active isolation lines and non-functional isolation lines are of the same width L.

5. The module of claim 4, wherein the width L is less than 100 micrometers.

6. The module of claim 1, wherein the elementary geometrical figure is selected from the group consisting of a circle, a square, a hexagon, an octagon, and a diamond.
